(19) United States
(12) Patent Application Publication
(10) Pub. No.: US 2025/0204132 A1
(43) Pub. Date: Jun. 19, 2025

(54) METHOD FOR MANUFACTURING AN OPTOELECTRONIC DEVICE FOR COLOR CONVERSION BY LOCALIZED DEPOSITION OF PHOTOLUMINESCENT PARTICLES ON PREDEFINED CONVERSION ZONES WITH A STRUCTURED SURFACE POTENTIAL

(71) Applicant: COMMISSARIAT A L'ENERGIE ATOMIQUE ET AUX ENERGIES ALTERNATIVES, Paris (FR)

(72) Inventors: Stéphane ALTAZIN, Grenoble Cedex 09 (FR); Aurélien SUHM, Grenoble Cedex 09 (FR); Jeremy BILDE, Grenoble Cedex 09 (FR); Etienne QUESNEL, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/981,064

(22) Filed: Dec. 13, 2024

(30) Foreign Application Priority Data
Dec. 14, 2023 (FR) 2314230

(51) Int. Cl. H10H 29/851; H10H 29/01

(52) U.S. Cl. CPC H10H 29/8516; H10H 29/0361

(57) ABSTRACT

The invention relates to a method for manufacturing an optoelectronic device (1) with a diode array (20), including the following steps:
producing an electret layer (30) having conversion zones (Zc) separated two-by-two by a spacing zone (Ze) with zero surface potential, where each conversion zone (Zc) is formed of a plurality of so-called polarized elementary zones (32) with non-zero surface potential, spaced apart two-by-two by a so-called non-polarized elementary zone (33) with zero surface potential, such that the conversion zone (Zc) has a structured surface potential;
producing color conversion pads (P), by placing the electret layer (30) in contact with a colloidal solution(S) containing photoluminescent particles (p).

### TECHNICAL FIELD

The field of the invention is that of methods for manufacturing optoelectronic devices including a diode array for emission and detection of an electroluminescent radiation, associated with color conversion pads. The invention has application, in particular, in display screens and image projectors.

### PRIOR ART

Optoelectronic devices including an array of identical light-emitting diodes partially covered by color conversion pads exist. Such optoelectronic devices can form display screens or image projection systems including an array of luminous pixels of different colors.

In such an optoelectronic device, each luminous pixel includes one or more light-emitting diodes associated with a color conversion pad. With the aim of obtaining suitable luminous pixels for emitting light of different colors, for example blues, greens or reds, the light-emitting diodes can be adjusted to each emit a same light, for example blue, and the green and red pixels include light conversion pads suitable for at least partially absorbing incident blue light and, in response, emitting green light or red light.

The light-emitting diodes are therefore preferably identical to one another, and emit light of the same wavelength. They can be formed from a semiconductor material comprising elements from column Ill and column V of the periodic table, such as a III-V compound, in particular gallium nitride (GaN), indium gallium nitride (InGaN) or aluminum gallium nitride (AlGaN). They are arranged so as to form an array of light-emitting diodes having a front face from which the generated light is transmitted.

The light conversion pads can be formed from a binder matrix including particles of a photoluminescent material such as yttrium aluminum garnet (YAG) activated by the cerium ion YAG:Ce. The photoluminescent particles can also be quantum dots, i.e. in the form of semiconductor nanocrystals, the quantum confinement of which is substantially three-dimensional. It can also involve nanoplatelets, i.e. nanoparticles having a substantially two-dimensional shape (two-dimensional quantum confinement).

The manufacturing method can include depositing then structuring a photoluminescent layer in order to form first light conversion pads, for example suitable for converting blue into red. These steps are repeated in order to form second light conversion pads, for example suitable for converting blue into green. However, this method has the drawback of being poorly suited to diode arrays with small pixel pitches, for example of order 5 μm, since there may be problems with alignment or covering of the light conversion pads by one another.

Document WO2014/136023A1 describes another manufacturing method which uses an electret layer covering the diode array. The method firstly comprises a step of inscribing electric charge patterns on the upper face of a dielectric layer in order to obtain the electret layer which is then locally charged. To do this, the tip of an atomic force microscope (AFM) is used to locally inject the electric charges. Then, a step of localized deposition of colloidal nanocrystals is carried out on the electric charge patterns. For this purpose, the electret layer is placed in contact with a colloidal solution containing the nanocrystals, which are naturally deposited on the electric charge patterns under the effect of a dielectrophoretic force. However, this method has, in particular, the drawback of having to inject the electric charges sequentially, by moving the AFM tip over the surface of the upper face in order to form the electric charge patterns there.

Document WO2021/023656A1 describes a similar method, where the electric charge patterns are defined by a stamping technique, i.e. by placing an electrically polarized stamp in contact with a dielectric layer intended to former the electret layer. The lower face of the stamp is structured to form polarized teeth, which come into contact with the dielectric layer. The electret layer, the upper face of which has the electric charge patterns, is thus obtained. Then, the electret layer is placed in contact with a colloidal solution, the nanocrystals present are the deposited on the electric charge patterns by dielectrophoresis. However, this method has, in particular, the drawback of needing to position the stamp precisely relative to the diode array. However, the uncertainty in positioning of the stamp relative to the diode array can become problematic, in particular for diode arrays with small pixel pitch, for example of order 5 μm. More specifically, this uncertainty or imprecision in the positioning can lead to poor positioning of the light conversion pads relative to the diodes, and thus to a degradation in the performance of the optoelectronic device.

### DESCRIPTION OF THE INVENTION

An objective of the invention is to overcome at least some of the drawbacks of the prior art, and more particularly to propose a method for manufacturing an optoelectronic device which has better performance.

For this purpose, the subject matter of the invention is a method for manufacturing an optoelectronic device, including the following steps:
providing a diode array, having a front face intended to receive or transmit light;
producing an electret layer extending on the front face of the diode array, an upper face of which, opposite the front face, has conversion zones, each being situated perpendicular to a diode and intended to be covered by a color conversion pad, separated two-by-two by a spacing zone with zero surface potential;
producing the color conversion pads by placing the electret layer in contact with a colloidal solution containing photoluminescent particles which are deposited on the electret layer in the conversion zones, thus forming the color conversion pads;
following the step of producing the electret layer, each conversion zone is formed of a plurality of so-called polarized elementary zones with non-zero surface potential spaced apart two-by-two by a so-called non-polarized elementary zone with zero surface potential, such that the conversion zone has a structured surface potential.

Some preferred, yet non-limiting, aspects of this method are as follows.

The polarized elementary zones can be symmetrically arranged relative to a center of the conversion zone.

Each conversion zone can include between three and nine polarized elementary zones, and preferably between three and seven polarized elementary zones.

The polarized elementary zones can all be situated at a distance from a border of the conversion zone.

The electret layer can have a homogeneous relative permittivity.

The electret layer can have a relative permittivity having a first value in the conversion zones and a second value greater than the first value outside of the conversion zones.

The electret layer can be formed of first portions situated in the conversion zones and made of a material having the first relative permittivity value, and second portions situated outside of the conversion zones and made of a material having the second relative permittivity value.

The electret layer can be formed of a continuous sublayer covering the diode array and made of a material having the first relative permittivity value, and portions covering the sublayer, situated outside of the conversion zones and made of a material having the second relative permittivity value.

The invention also relates to an optoelectronic device, including:
a diode array having a front face intended to receive or transmit light;
an electret layer, extending on the front face of the diode array, an upper face of which, opposite the front face, has conversion zones, each being situated perpendicular to a diode and intended to be covered by a color conversion pad, separated two-by-two by a spacing zone with zero surface potential;
color conversion pads, situated on the electret layer and positioned in the conversion zones;
where each conversion zone is formed of a plurality of so-called polarized elementary zones with non-zero surface potential spaced apart two-by-two by a so-called non-polarized elementary zone with zero surface potential, such that the conversion zone has a structured surface potential.

The diodes can have light emission or absorption properties identical to one another.

The diodes can be made from an organic or inorganic semiconductor compound.

The invention also relates to a method for manufacturing an optoelectronic device, including the following steps:
providing a diode array, having a front face intended to receive or transmit light;
an electret layer, extending on the front face of the diode array, an upper face of which, opposite the front face, has conversion zones, each being situated perpendicular to a diode and intended to be covered by a color conversion pad, separated two-by-two by a spacing zone with zero surface potential;
producing the color conversion pads by placing the electret layer in contact with a colloidal solution containing photoluminescent particles which are deposited on the electret layer in the conversion zones, thus forming the color conversion pads;
after producing the electret layer, the surface potential in each conversion zone is uniformly non-zero; the conversion zones have a first relative permittivity value and the spacing zones have a second relative permittivity value greater than the first value.

The electret layer can be formed of first portions situated in the conversion zones and made of a material having the first relative permittivity value, and second portions situated outside of the conversion zones and made of a material having the second relative permittivity value.

The electret layer can be formed of a continuous sublayer covering the diode array and made of a material having the first relative permittivity value, and portions covering the sublayer, situated outside of the conversion zones and made of a material having the second relative permittivity value.

The invention also relates to an optoelectronic device, including:
a diode array having a front face intended to receive or transmit light;
an electret layer, extending on the front face of the diode array, an upper face of which, opposite the front face, has conversion zones, each being situated perpendicular to a diode and intended to be covered by a color conversion pad, separated two-by-two by a spacing zone with zero surface potential;
color conversion pads, situated on the electret layer and positioned in the conversion zones;
where the surface potential in each conversion zone is uniformly non-zero; the conversion zones have a first relative permittivity value and the spacing zones have a second relative permittivity value greater than the first value.

### BRIEF DESCRIPTION OF THE DRAWINGS

Other aspects, aims, advantages and features of the invention will appear better upon reading the following detailed description of preferred embodiments thereof, given as a non-limiting example, and made with reference to the appended drawings wherein:

FIGS. 1A to 1C illustrate various steps of a method for manufacturing an optoelectronic device, where the conversion zones have a uniformly non-zero surface potential;

FIG. 2 illustrates a variation of the vertical component of the electric field gradient, in the configuration of FIG. 1B;

FIG. 3A is a schematic partial view, in cross-section, of an optoelectronic device where the conversion zones have a uniformly non-zero surface potential, according to another design of the diode array;

FIG. 3B illustrates a variation of the vertical component of the electric field gradient, in the configuration of FIG. 3A;

FIG. 4A is a schematic partial view, in cross-section, of an optoelectronic device according to an embodiment where the conversion zones have a structured surface potential;

FIG. 4B is a view from above of the conversion zone illustrating the design of the polarized elementary zones;

FIG. 4C illustrates a variation of the vertical component of the electric field gradient, in the configuration of FIG. 4A;

FIG. 5A is a schematic partial view, in cross-section, of an optoelectronic device according to another embodiment where the conversion zones have a structured surface potential;

FIG. 5B illustrates a variation of the vertical component of the electric field gradient, in the configuration of FIG. 5A;

FIGS. 6A to 6F are views from above of a conversion zone of an optoelectronic device according to various embodiments;

FIGS. 7A to 7C illustrate the variation of the vertical component of the electric field gradient, for various embodiments of the optoelectronic device;

FIG. 8A illustrates a variation of the vertical component of the electric field gradient, for an optoelectronic device according to an embodiment where the electret layer has a homogeneous relative permittivity;

FIG. 8B is a schematic partial view, in cross-section, an optoelectronic device according to an embodiment where the electret layer has an inhomogeneous relative permittivity;

FIG. 8C illustrates a variation of the vertical component of the electric field gradient, for the configuration of FIG. 8B;

FIG. 9A is a schematic partial view, in cross-section, of an optoelectronic device according to an embodiment where the electret layer has an inhomogeneous relative permittivity and where the conversion zones have a uniformly non-zero surface potential;

FIG. 9B illustrates a variation of the vertical component of the electric field gradient, for the configuration of FIG. 9A;

FIG. 10A is a schematic partial view, in cross-section, of an optoelectronic device according to another embodiment where the electret layer has an inhomogeneous relative permittivity and where the conversion zones have a uniformly non-zero surface potential;

FIG. 10B illustrates a variation of the vertical component of the electric field gradient, for the configuration of FIG. 10A; and

FIGS. 11A to 11E illustrate various steps of a method for manufacturing an optoelectronic device similar to that of FIG. 9A.

### DETAILED DISCLOSURE OF PARTICULAR EMBODIMENTS

In the figures and in the following description, the same references represent identical or similar elements. In addition, the different elements are not plotted to scale so as to favor clarity of the figures. Moreover, the different embodiments and variants are not exclusive of one another and could be combined together. Unless stated otherwise, the terms “substantially”, “about”, “in the range of” mean within a 10% margin, and preferably within a 5% margin. Moreover, the terms “comprised between . . . and . . . ” and the like mean that the bounds are included, unless stated otherwise.

The invention relates to a method for manufacturing an optoelectronic device including a diode array, for which at least a portion of the diodes is covered by color conversion pads, so as to form an array of luminous pixels of different colors. The diodes can be emitting diodes such that the optoelectronic device can be, for example, a display screen. They can thus be organic (OLED) or inorganic (LED) light-emitting diodes. Alternatively, the diodes can be detecting diodes such that the optoelectronic device can be a matrix-array photodetector. This can involve organic or inorganic photodetectors.

The color conversion pads are produced by localized deposition of photoluminescent particles on an electret layer. Each conversion pad is situated opposite a diode.

In general, an electret layer is a dielectric layer containing electric charges or a semi-permanent dipole polarization. The electret layer also has a non-zero surface potential on at least a portion of its upper face. This is manifest by the fact that the electret layer emits an external electric field in the absence of an applied field.

In the context of the invention, a conversion zone is defined as being a predefined surface of the electret layer situated perpendicular to a diode, and covered or intended to be covered by a conversion pad. The surface potential, in such a conversion zone, is not uniformly non-zero as in the prior art (i.e. non-zero over the entire surface of the conversion zone), but is structured there. In other words, each conversion zone is formed of a plurality of so-called polarized elementary zones, where the surface potential is non-zero, spaced apart two-by-two by a non-polarized elementary zone where the surface potential is zero.

Thus it would appear that the localized deposition of photoluminescent particles in the conversion zone is more homogeneous than in the prior art, thus improving the properties of the optoelectronic device. Moreover, it would appear that the localized deposition of photoluminescent particles outside of the conversion zones is reduced, which improves the contrast of the pixels of the optoelectronic device.

In general, the color conversion pads are formed of particles of at least one photoluminescent material, and preferably nanoparticles for which at least one maximum dimension is between 0.2 nm and 1000 nm, for example between 20 nm and several hundred nanometers. The size and/or composition of the photoluminescent particles are chosen according to the desired wavelength of light. Any particle shape is possible, for example spherical angular, flattened, elongate, etc.

The photoluminescent particles can also be quantum dots, i.e. in the form of semiconductor nanocrystals, the quantum confinement of which is substantially three-dimensional. The average size of the quantum dots can then be between 0.2 nm and 50 nm, for example between 1 nm and 30 nm. It can also involve nanoplatelets, i.e. nanoparticles having an essentially two-dimensional shape, with a length which can be of order 20 nm to several hundred nanometers. In addition, the smallest dimension (thickness) is less than the two other dimensions of length and width, preferably with a ratio of at least 1.5.

The photoluminescent particles can, in particular, be formed or at least one semiconductor compound, which can be chosen for example, from cadmium selenide (CdSe), indium phosphide (InP), gallium indium phosphide (InGaP), cadmium sulfide (CdS), zinc sulfide (ZnS), cadmium oxide (CdO) or zinc oxide (ZnO), cadmium zinc selenide (CdZnSe), zinc selenide (ZnSe) doped, for example, with copper or manganese, graphene or any other suitable semiconductor materials. The nanoparticles can also have a core/shell structure, such as CdSe/ZnS, CdSe/CdS, CdSe/CdS/ZnS, PbSe/PbS, CdTe/CdSe, CdSe/ZnTe, InP/ZnS or others. The particles can also have a perovskite crystal structure, including atoms such as those listed for the nanoparticles, but also Cs, Mn or Br.

Furthermore, the light conversion pads are suitable for at least partially converting incident light of a first wavelength λ₁ into light of a longer wavelength λ₂. By way of illustration, they can also be suitable for absorbing blue light, i.e. light for which the wavelength is between about 440 nm and 490 nm, and for emitting in the green, i.e. at a wavelength between about 495 nm and 560 nm, or even in the red, i.e. at a wavelength between 600 nm and 650 nm. Here, wavelength shall mean the wavelength at which the emission spectrum has an intensity peak.

By way of illustration only, the diodes can be emitting and have an emission spectrum in the visible or infrared (for example in the NIR or SWIR), or even ultraviolet (200-400 nm). In the case of an emitting diode array, the incident light is the radiation emitted by the diodes, whereas in the case of photodiodes, it is the light coming from an external environment and directed towards the photodiodes. In the latter case, the diodes are then suitable for absorbing incident light of different wavelengths that are all contained in the same predefined absorption spectrum.

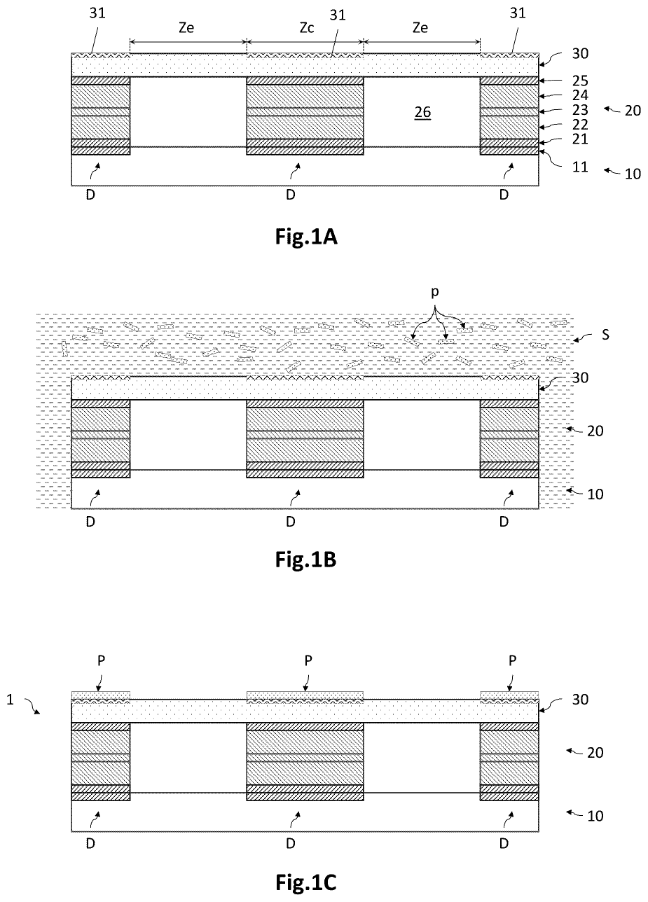

FIGS. 1A to 1C illustrate various steps of an exemplary method for manufacturing an optoelectronic device 1, highlighting a problem linked to the localized deposition of photoluminescent particles p in the conversion zone Zc and outside the conversion zone Zc. In this example, the diodes D are light-emitting diodes.

Here and in the rest of the description, a direct three-dimensional orthogonal reference frame XYZ is defined, where the X and Y axes form a main plane in which the diode array 20 extends, and where the Z axis is oriented along the thickness of the diode array 20 towards the front face. The terms ‘lower’ and ‘upper’ are defined relative to a positioning increasing along the +Z direction.

With reference to FIG. 1A, an array 20 of light-emitting diodes D is provided. In this case, the diodes D are resting on a control substrate 10, and are electrically polarized here by one or more lower electrode layers 21 and by one or more upper electrode layers 25. Other configurations are possible, in particular in the case where the control substrate 10 is electrically conductive. The diode array 20 has a rear face, by which it is assembled and connected to the control substrate 10, and a front face, opposite the rear face, which is intended to receive or transmit light. In this example, where the diodes D are emitting, the front face transmits the light emitted by the diodes. In this example, it is intended to produce color conversion pads above the diodes shown. However, certain diodes cannot be associated with color conversion pads.

In this example, the control substrate 10 includes a CMOS-type control circuit (not shown), and has electrical connection pads 11 which are flush with the upper face and come into contact with lower electrode layers 21 of the diodes D. Here, these lower electrode layers 21 are distinct from one another in the sense that each lower electrode layer 21 of a diode D is physically distinct from that of the adjacent diode. This configuration is described in detail in document WO2017/194845 A1. Other configurations are possible.

Here, the diodes D are inorganic light-emitting diodes. They can be produced conventionally, for example by epitaxy of semiconducting layers starting from a growth substrate, then by transfer to the control substrate 10. Each diode D can be formed by a stack of: a lower semiconducting portion 22 (situated on the side of the control substrate), doped with a first conductivity type, for example p-type, in electrical contact with a lower electrode layer 21; an active zone 23 where the light radiation is emitted from the light-emitting diode; and an upper semiconducting portion 24 doped with a second conductivity type, for example n-type, in electrical contact with an upper electrode layer 25. The diodes D can be produced from the same semiconductor compound, for example based on a III-V compounds such as GaN, InGaN or AlGaN. An electrically insulating filler material 26 fills the space situated between the diodes D.

The diodes D are preferably structurally identical, so that the emitted light radiation is identical from one diode to another in terms of wavelength. In this example, the diodes D are suitable for emitting light radiation in the blue, i.e. for which the emission spectrum has an intensity peak at a wavelength between about 440 nm and 490 nm.

The front face of the diode array 20 is covered by an electret layer 30. The electret layer 30 is made of at least one dielectric material, which is for example inorganic, such as a silicon oxide, nitride or oxynitride, for example SiO₂, Si₃N₄, Al₂O₃ (in particular in the case of OLED), among others. It can have a thickness of order several hundreds of nanometers, for example about 400 nm. It is noted that organic dielectric materials can also be suitable, such as PMMA, PVDF, PET, COC, etc.

A conversion zone Zc is defined as being a surface of the electret layer 30 situated opposite (perpendicular to) a diode D, and more precisely to its active layer 23. In this example, the surface potential 31 is uniformly non-zero (i.e. non-zero over the entire surface of the zone Zc). The conversion zones Zc are separated laterally two-by-two by a spacing zone Ze where the surface potential is zero (more precisely, the surface potential of each spacing zone Ze is uniformly zero, i.e. zero over the entire surface of the zone Ze).

The formation of conversion zones Zc, i.e. the formation of the non-zero surface potential 31 in the conversion zones Zc, can be carried out in various ways. It is possible to use an AFM tip, as in document WO2014/136023A1, or a stamping technique as in document WO2021/023656A1. It is also possible to locally depolarize an electret layer 30 for which the surface potential is initially non-zero over the entire front face through optical means, by means of activating the diodes, as described in patent application FR2308637 filed on 10 Aug. 2023. It is also possible to locally produce an electrostatic polarization of the electret layer for which the surface potential is initially zero over the entire front face, by means of an activation of the upper electrodes, as described in patent application FR2309260 filed on 4 Sep. 2023.

Thus, the conversion zones Zc with uniformly non-zero surface potential 31 are only present opposite the diodes D. In other words, the electret layer 30 has a zero surface potential everywhere except in the conversion zones Zc opposite the diodes.

With reference to FIG. 1B, the color conversion pads are then produced by localized deposition of photoluminescent particles p on the electret layer 30 on the conversion zones Zc. This is done in a similar manner to that described in documents WO2014/136023A1 and WO2021/023656A1. Thus, a colloidal solution S containing the photoluminescent particles p is placed in contact with the upper face of the electret layer 30. The photoluminescent particles p are suitable for converting blue light into, for example, red light. The entire stack can then be immersed in the colloidal solution S, or a drop of such a solution can be deposited on the electret layer 30. Due to the non-zero surface potential 31 situated in the conversion zones Zc, a non-uniform electric field is generated which causes a localized deposition of photoluminescent particles p by dielectrophoresis. The photoluminescent particles p are also deposited substantially on the conversion zones Zc (and therefore opposite the diodes). The contact time of the colloidal solution S on the electret layer 30 depends, in particular, on the quantity of photoluminescent particles p to be deposited and therefore on the desired thickness of conversion pads P, as well as on the value of the surface potential. By way of example, the thickness of the conversion pads P can be of order several hundred nanometers, for example equal to about 400 nm. The colloidal solution S is then removed and the electret layer 30 can be dried.

With reference to FIG. 1C, an optoelectronic device 1 is obtained where the conversion pads P are substantially present in the conversion zones Zc, and thus opposite the diodes D. A fine layer encapsulation (for example made of Al₂O₃) of the conversion pads P can then be carried out (not shown).

The preceding steps can then be repeated in order to produce other color conversion pads situated opposite other diodes, forming for example green pixels. More specifically, the color conversion pads previously described are suitable for converting blue light (wavelength between about 440 nm and 490 nm) into red light (wavelength between 600 nm and 650 nm). By contrast, in this case the color conversion pads are suitable for converting blue light into a green light (wavelength between about 495 nm and 560 nm).

However, it would appear that the photoluminescent particles p cannot be deposited homogeneously in the conversion zones Zc, which leads to the forming of conversion pads P for which the thickness of each is non-uniform, so that the conversion properties of the pads P are not spatially uniform. Moreover, it would appear that the photoluminescent particles p can be deposited outside of the conversion zones Zc, thus degrading the contrast associated with each emitting pixel.

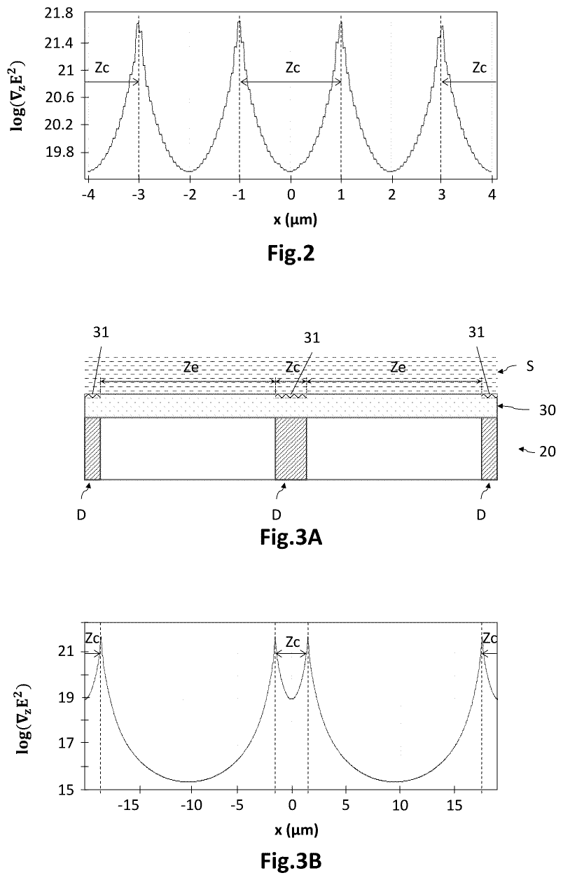

FIG. 2 illustrates the spatial variation of the intensity (on a log scale) of the vertical component ∇₂E² of the gradient of the squared norm of the electric field E, to which the dielectrophoretic force F is proportional, calculated at a distance of 100 nm above the electret layer 30, in a similar structural configuration to that of FIG. 1B.

In general, a photoluminescent particle of dimension r and dielectric constant Ep situated in a constant dielectric solution εₘ (dielectric permittivity) undergoes, due to the spatial inhomogeneity of the electric field \vec{E}, a dielectrophoretic force \vec{F} defined by the formula:

$$\vec{F} = 2 \times π \times {r}^{3} \times {ε}_{m} \times \frac{{ε}_{p} - {ε}_{m}}{{ε}_{p} + 2 \times {ε}_{m}} \times ∇ ( {‖ \vec{E} ‖}^{2} )$$

In this configuration, the diodes D have a lateral dimension of 2 μm and are periodically arranged with a pitch of 4 μm. The conversion zones Zc also have a lateral dimension of 2 μm and are spaced apart from one another by 2 μm. The surface potential 31 is uniformly non-zero in the conversion zones Zc, and is uniformly zero in the spacing zones Ze. In this case, the filling factor FF_{d} of diodes is equal to 50% (=2 μm/4 μm).

Furthermore, a relative permittivity ε_{r,e} of the electret layer 30 is considered, which is homogeneous (spatially uniform) in the entire layer and equal to 4, and a relative permittivity ε_{r,m} of the colloidal solution is also homogeneous and equal to 2.

It would appear that the dielectrophoretic force F_{z} is not constant in the conversion zones Zc. Indeed, it has a maximum, situated at the border of the conversion zone Zc, with a value here of 21.7, and a minimum situated at the center of the conversion zone Zc, with a value here of 19.5.

Moreover, the intensity of the force F_{z} decreases outside of the conversion zone Zc, down to a minimum of 19.5 also situated at the center of the spacing zone Ze. Moreover, it would appear that these minima of the dielectrophoretic force F_{z} are situated at the same distance from the border of the conversion zone Zc, so that the rate of decrease is symmetric on either side of this border. Consequently, the variation of the force F₂ is identical in the conversion zones Zc and in the spacing zones Ze, such that from the point of view of the dielectrophoretic force, it is not possible to distinguish the conversion zones Zc from the spacing zones Ze.

In addition, the photoluminescent particles p are deposited first on the border of the conversion zone Zc, then on either side of this in a substantially symmetrical manner.

This leads to the formation of conversion pads P, which not only do not have a uniform thickness in the conversion zones Zc, but moreover are not correctly positioned. The conversion properties are therefore degraded, and the contrast of the luminous pixels is not optimum.

FIG. 3A is a schematic partial view, in cross-section, of a diode array 20 covered by an electret layer 30 and by a colloidal solution S (the photoluminescent particles p are not shown), in another structural configuration. As for FIG. 1B, the electret layer 30 includes conversion zones Zc situated perpendicular to the diodes D, where the surface potential 31 is uniformly non-zero (i.e. non-zero over the entire surface of the zone Zc), separated two-by-two by spacing zones Ze with uniformly-zero surface potential (i.e. zero over the entire surface of the zone Ze).

The conversion zones Zc have a lateral dimension of 2 μm, and are arranged periodically with a pitch of 18 μm. The spacing zones Ze also have a lateral dimension of 16 μm. The filling factor FF_{d} is thus 11% (=2 μm/18 μm). In this example, the electret layer 30 has a homogeneous relative permittivity equal to 4, and the colloidal solution S has a homogeneous relative permittivity equal to 2.

FIG. 3B illustrates the spatial variation of the intensity (on a log scale) of the vertical component ∇₂E² of the gradient of the squared norm of the electric field E, to which the dielectrophoretic force F is proportional, calculated at a distance of 100 nm above the electret layer 30, in the structural configuration of FIG. 3B.

As for FIG. 2, it would appear that the dielectrophoretic force F₂ is not constant in the conversion zones Zc. Indeed, it has a maximum, located at the border of the conversion zone Zc, in this case with a value, on a log scale (∇₂E²), of 21.8, and a minimum, situated at the center of the conversion zone Zc, with a value in this case of 18.9.

Moreover, the intensity of the force F_{z} decreases outside of the conversion zone Zc to a minimum of 15.4 at the center of the spacing zone Ze. This minimum is thus significantly lower than that present in the conversion zone Zc.

Insofar as the center of the spacing zone Ze is further away from the border, the force F_{z} has, in the spacing zone, a rate of decrease from the maximum of 21.8 slightly higher than that defined in the conversion zone Zc.

Also, although the photoluminescent particles p are mainly deposited in the conversion zone Zc, a deposition will take place in the spacing zone Ze, starting from the border of the conversion zone Zc. Moreover, the localized deposition in the conversion zone Zc is not uniform: it will be larger at the border than at the center of the conversion zone Zc, leading to a non-uniform conversion rate.

The inventors have shown that the fact of structuring the surface potential in the conversion zones Zc makes it possible to limit the disadvantages of the configurations which have just been presented. The surface potential is referred to as “structured” insofar as each conversion zone Zc has a plurality of elementary zones 32 with non-zero surface potential (more precisely uniformly non-zero, i.e. non-zero over the entire surface of the zone 32) spaced apart two-by-two by an elementary zone 33 with zero surface potential (more precisely uniformly zero, i.e. zero over the entire surface of the zone 33). Thus, the conversion zones Zc of FIG. 1A to 1C are characterized in that the surface potential is uniformly non-zero, i.e. non-zero over the entire surface of the zone Zc.

More specifically, a structured surface potential will make it possible to improve the homogeneity of the localized deposition of the photoluminescent particles p in the conversion zone Zc, and thus the thickness of the conversion pad P, while limiting the deposition outside the conversion zones Zc (thus differentiating, in terms of dielectrophoretic force, the conversion zones Zc from the spacing zones Ze).

Thus, a so-called “polarized” elementary zone 32 is a portion of the surface of the conversion zone Zc where the surface potential is non-zero over the entire surface of the zone 32 (thus uniformly non-zero). Moreover, a so called non-polarized elementary zone 33 is a portion of the surface of the conversion zone Zc where the surface potential is zero over the entire surface of the zone 33 (thus uniformly zero). Moreover, each conversion zone Zc is formed of a plurality of polarized elementary zones 32 separated two-by-two by a non-polarized elementary zone 33.

In each conversion zone Zc, the polarized elementary zones 32 are preferably designed to be symmetric relative to an axis contained in the XY plane and passing through the center of the conversion zone Zc. By way of example, the polarized elementary zones 32 can be symmetrically arranged relative to the X-axis and/or of the Y-axis.

Along a given axis of the XY plane, for example along the X-axis, each conversion zone Zc can include at least two polarized elementary zones 32, for example between two and twenty polarized elementary zones 32. Preferably, it includes between three and nine polarized elementary zones 32, or even preferably between three and seven polarized elementary zones 32. Thus, the homogeneity is improved for the localized deposition of the photoluminescent particles p in the conversion zone Zc. The polarized elementary zones 32 can have a dimension, for example, of order ⅕^{th}, 1/10^{th}, or even 1/20^{th} of the dimension of the conversion zone Zc along the same axis considered (for example along the X-axis). Hence, by way of example, for a conversion zone Zc of width 2 μm, the polarized elementary zones 32 can have a width of about 100 to 500 nm. The unpolarized elementary zones 33 can have a width of the same order.

The polarized elementary zones 32 can be arranged in each conversion zone Zc starting from the border thereof, i.e. by being attached to this. In an alternative, they may not be attached at the border, but can be spaced apart. This configuration is advantageous, because it makes it possible to avoid the dielectrophoretic force having an intensity peak located at the border, which limits the deposition of the photoluminescent particles p in the spacing zone close to the border. Thus the contrast of the luminous pixels is improved.

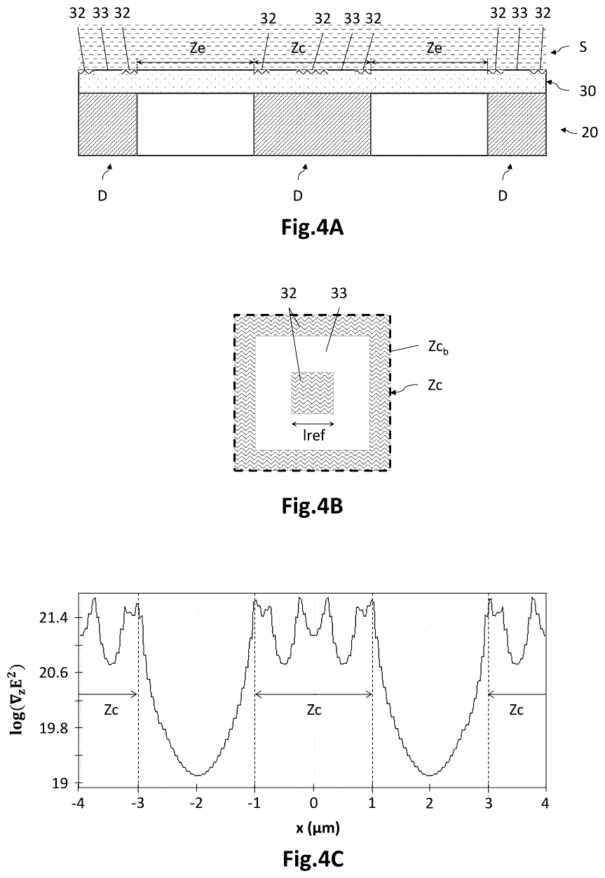

FIG. 4A is a schematic partial view, in cross-section, of a diode array covered by an electret layer, which is in contact with a colloidal solution. FIG. 4B is a view from above of the design of the polarized elementary zones 32 situated in a conversion zone Zc. FIG. 4C illustrates the spatial variation of the intensity (on a log scale) of the vertical component ∇₂E² of the gradient of the squared norm of the electric field E, to which the dielectrophoretic force F is proportional, calculated at a distance of 100 nm above the electret layer 30, in the structural configuration of FIG. 4A.

In this configuration, the diodes D have a lateral dimension of 2 μm and are periodically arranged with a pitch of 4 μm. The conversion zones Zc also have a lateral dimension of 2 μm and are spaced apart from one another by 2 μm. The electret layer 30 has a homogeneous relative permittivity equal to 4, and the colloidal solution S has a homogeneous relative permittivity equal to 2.

Each conversion zone Zc includes a polarized elementary zone 32 of side 500 nm, situated at the center the conversion zone Zc, spaced apart by a distance of 500 nm along the X and Y axes of a peripheral polarized elementary zone 32 of width 250 nm. This is attached to the border Zc_{b} of the conversion zone Zc. Hence, along the X- or Y-axis, the conversion zone Zc includes three polarized elementary zones 32 separated two-by-two by a non-polarized elementary zone 33.

The dielectrophoretic force thus has a spatial variation in the conversion zone Zc which is reduced compared to the variation illustrated in FIG. 2. Hence, the localized deposition of photoluminescent particles p is made more uniform here. The positioning of the conversion pad P is also improved, insofar as the conversion zone Zc is now distinguishable relative to the spacing zone Ze, in terms of dielectrophoretic force. The conversion pad P will also be correctly positioned opposite the diode D, and no longer straddling the border as in the case of FIG. 2.

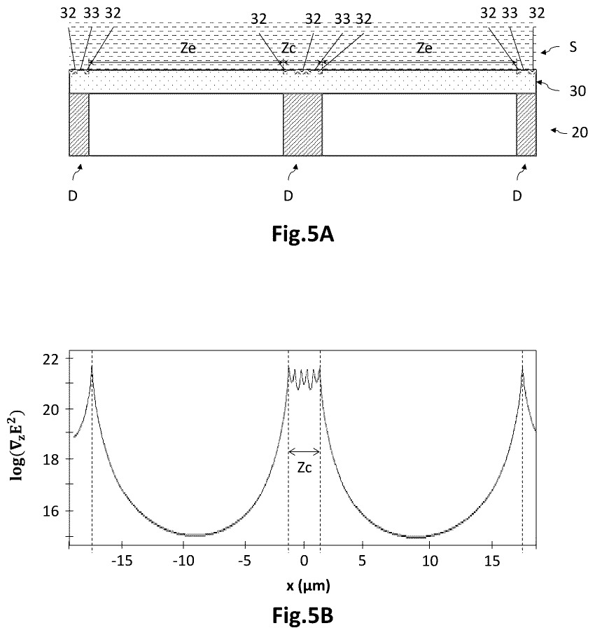

FIG. 5A is a schematic partial view, in cross-section, of a diode array covered by an electret layer, which is in contact with a colloidal solution. FIG. 5B illustrates the spatial variation of the intensity (on a log scale) of the vertical component ∇₂E² of the gradient of the squared norm of the electric field E, to which the dielectrophoretic force F is proportional, calculated at a distance of 100 nm above the electret layer 30, in the structural configuration of FIG. 5A.

In this configuration, the diodes D have a lateral dimension of 3 μm and are periodically arranged with a pitch of 19 μm. The conversion zones Zc also have a lateral dimension of 3 μm and are spaced apart from one another by 16 μm. The electret layer 30 has a homogeneous relative permittivity equal to 4, and the colloidal solution S has a homogeneous relative permittivity equal to 2.

Each conversion zone Zc includes a polarized elementary zone 32 of side 500 nm, situated at the center the conversion zone Zc, spaced apart along the X and Y axes of a peripheral polarized elementary zone 32 of width 250 nm. This is attached to the border Zc_{b} of the conversion zone Zc. Hence, along the X- or Y-axis, the conversion zone Zc includes three polarized elementary zones 32 separated two-by-two by a non-polarized elementary zone 33.

The dielectrophoretic force thus has a spatial variation in the conversion zone Zc which is reduced compared to the variation illustrated in FIG. 3B. Hence, the localized deposition of photoluminescent particles p is made more uniform here. The positioning of the conversion pad P is also improved, insofar as the conversion zone Zc is now distinguishable relative to the spacing zone Ze, in terms of dielectrophoretic force. The conversion pad P will also be correctly positioned opposite the diode D.

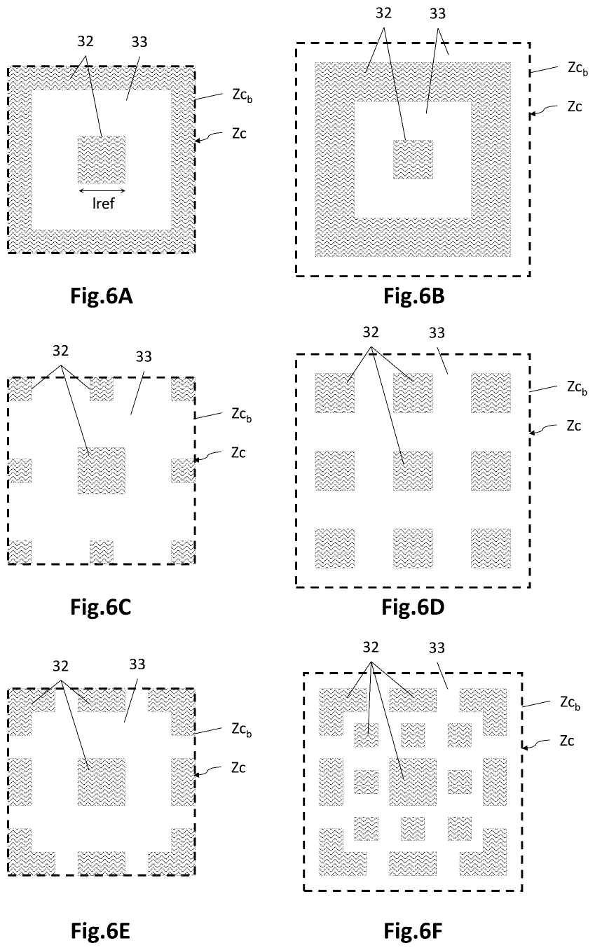

FIGS. 6A to 6F are views from above of various design examples of the polarized elementary zones 32 in a conversion zone Zc. These examples are given by way of illustration, it being understood that other designs are obviously possible. Here, the conversion zone Zc has a square shape in the XY plane, but other shapes are possible (rectangular, polygonal, circular, etc.).

FIG. 6A illustrates an identical design to that of FIG. 4B. The conversion zone Zc comprises three polarized elementary zones 32 along the X-axis and along the Y axis. The central polarized elementary zone 32 has a width Iref, and the peripheral polarized elementary zone 32 has a width Iref/2. This extends from the border Zc_{b} of the conversion zone Zc, i.e. being attached to the border. Moreover, here it extends continuously along the border Zc_{b}. Furthermore, the polarized elementary zones 32 are spaced apart by a non-polarized elementary zone 33 of width Iref.

FIG. 6B illustrates a design which differs from that of FIG. 6A substantially in that the peripheral polarized elementary zone 32 in this case has a width Iref equal to that of the central polarized elementary zone 32. Moreover, the peripheral polarized elementary zone 32 is not attached to the border Zc_{b}, but is spaced apart by a non-polarized elementary zone 33 in this case of width Iref/2.

FIG. 6C illustrates a design which differs from that of FIG. 6A substantially in that the mutually distinct lateral polarized elementary zones 32 are distributed along the border, and thus surround the central polarized elementary zone 32. Here, they have a width Iref/2 and are attached to the border Zc_{b}.

FIG. 6D illustrates a design which differs from that of FIG. 6A substantially in that the lateral polarized elementary zones 32 have a width Iref. They are spaced apart from one another along the X-axis and the Y-axis, by a non-polarized elementary zone 33 of width Iref. They are also spaced apart from the border, here by a width Iref/2.

FIG. 6E illustrates a design which differs from that of FIG. 6C substantially in that the lateral polarized elementary zones 32 are not all identical to one another. Those situated at the corner of the conversion zone Zc have an L shape, where the two branches in this case have the same length Iref and a width Iref/2. Those situated along the side of the conversion zone Zc have a length Iref and a width Iref/2.

FIG. 6F illustrates a design which differs from that of FIG. 6E substantially in that the lateral polarized elementary zones 32 are distanced from the border, in this case by a width Iref/2 along the X-axis and the Y-axis. Moreover, intermediate polarized elementary zones 32 are situated between the central polarized elementary zone 32 and the lateral polarized elementary zones 32 along the X and Y axes. In this case they are square-shaped with side Iref/2.

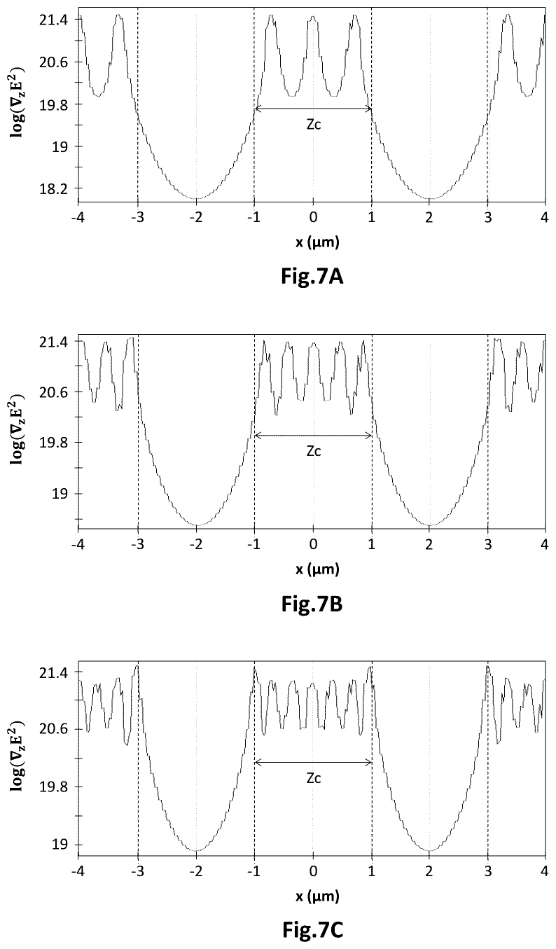

FIGS. 7A to 7C illustrate a spatial variation of the intensity (on a log scale) of the vertical component ∇₂E² of the gradient of the squared norm of the electric field E, calculated at a distance of 100 nm above the electret layer 30, for various designs of the polarized elementary zones 32 in the conversion zones Zc. In this case, the conversion zones Zc have a dimension of 2 μm and are spaced apart from one another by a spacing zone of 2 μm. The electret layer 30 has a homogeneous relative permittivity equal to 4, and the colloidal solution has a homogeneous relative permittivity equal to 2.

In FIG. 7A, each conversion zone Zc has three polarized elementary zones 32 with a width of 125 nm, including a central zone 32 and two lateral zones 32 at a distance from the border Zc_{b}. The filling factor, along the X-axis, is 19% (3×0.125/2) in this case. It is observed that the conversion zone Zc is easily distinguishable from the spacing zones Ze, from the point of view of the dielectrophoretic force, which improves the positioning of the conversion pad P as well as the homogeneity of thickness. Moreover, the fact that the lateral polarized elementary zones 32 are at a distance from the border makes it possible to reduce the intensity of the dielectrophoretic force, which then limits the deposition of the photoluminescent particles p in the spacing zones Ze, close to the conversion zone Zc, thus improving the contrast of the luminous pixels.

In FIG. 7B, the conversion zone Zc comprises five polarized elementary zones 32 of width 125 nm. The lateral polarized elementary zones 32 are at a distance from the border. It is observed that this configuration makes it possible to further improve the positioning of the conversion pad P opposite the diode, to improve the uniformity of thickness of the conversion pad P, and to limit the deposition of the photoluminescent particles p in the spacing zones Ze, close to the conversion zone Zc.

In FIG. 7C, the conversion zone Zc comprises seven polarized elementary zones 32 of width 125 nm. The lateral polarized elementary zones 32 are attached to the border. If the positioning of the conversion pad P opposite the diode and the uniformity of thickness of the conversion pad P are further improved, it is observed that the presence of the lateral polarized elementary zones 32 attached to the border can lead to a deposition of photoluminescent particles p in the spacing zones Ze close to the border of the conversion zone Zc.

According to an embodiment, the electret layer can be formed of a plurality of portions of materials having a different relative permittivity.

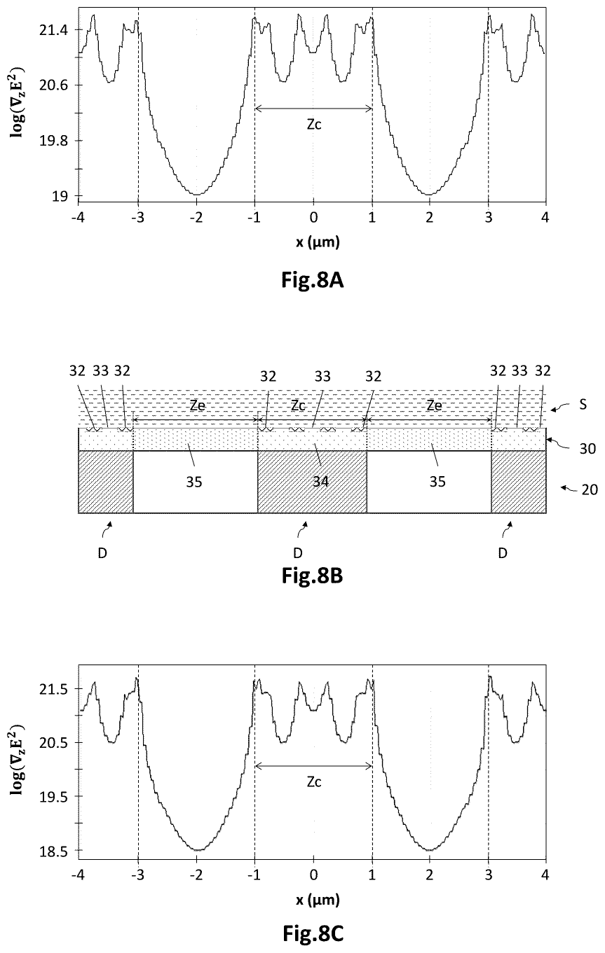

In this respect, FIGS. 8A to 8C illustrate a comparison between a configuration where the electret layer is homogeneous, i.e. having the same relative permittivity value everywhere in the electret layer, and a configuration where the electret layer is not homogeneous in terms of relative permittivity.

First, a configuration is considered where the electret layer has a constant (uniform) relative permittivity in the entire layer.

FIG. 8A illustrates a spatial variation of the intensity (on a log scale) of the vertical component ∇₂E² of the gradient of the squared norm of the electric field E, calculated at a distance of 100 nm above the electret layer 30, for a configuration where the electret layer is homogeneous (relative permittivity constant everywhere in the layer).

In this configuration, the diodes have a lateral dimension of 2 μm and are periodically arranged with a pitch of 4 μm. The conversion zones Zc also have a lateral dimension of 2 μm and are spaced apart from one another by 2 μm. The electret layer has a uniform relative permittivity equal to 4, and the colloidal solution has a uniform relative permittivity equal to 2. The conversion zone Zc is structured so as to form four polarized elementary zones 32 along the X-axis.

FIG. 8B is a schematic partial view, in cross-section, of a diode array 20 covered by an electret layer 30 and a colloidal solution S.

The configuration is similar to that described with reference to FIG. 8A, and differs from it only in that the electret layer 30 is not homogeneous but is formed of a succession of distinct portions 34, 35 having different relative permittivity. Hence, here, the portions 34 opposite the diodes have a relative permittivity of 4 and are made of a so-called low-k material, for example a silicon oxide or nitride. The portions 35 situated between the diodes have a high relative permittivity, here equal to 20, and are made of a so-called high-k material, for example a titanium or tantalum oxide.

FIG. 8C illustrates a spatial variation of the intensity (on a log scale) of the vertical component ∇₂E² of the gradient of the squared norm of the electric field E, calculated at a distance of 100 nm above the electret layer 30, for the configuration of FIG. 8B. It is observed that the variation is similar, however it has a larger minimum in the spacing zones Ze, here 18.5 instead of 19 in the case of FIG. 8A. The risk of depositing photoluminescent particles p in the spacing zones Ze is also reduced, and the deposition takes place more in the conversion zones Zc.

According to another embodiment, the conversion zones Zc can be unstructured and can thus have a uniformly non-zero surface potential. In this case, a relative permittivity is defined in the conversion zones Zc and in the spacing zones Ze.

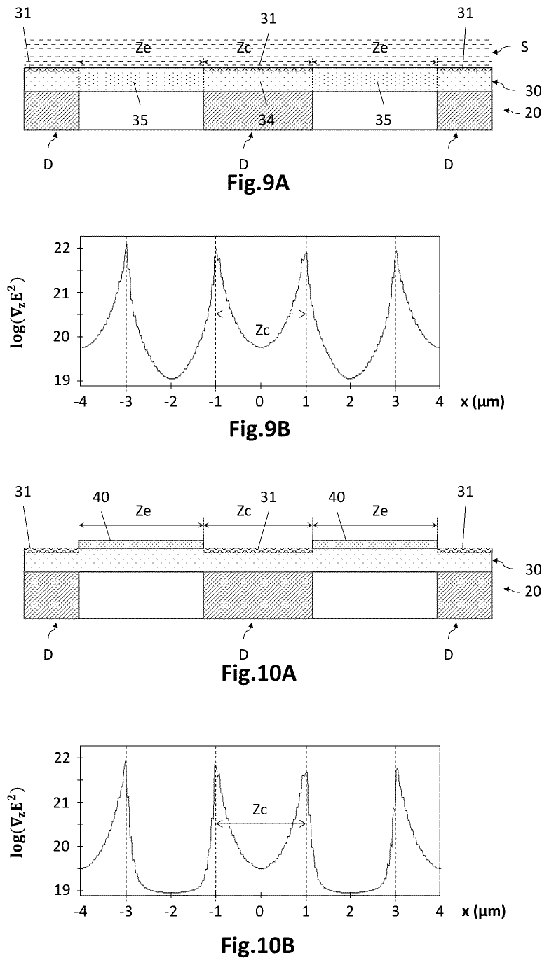

As illustrated by FIG. 9A, in the case where the electret layer 30 is inhomogeneous and is formed of a succession of portions 34, 35 of materials having a different relative permittivity, the relative permittivity of the conversion zones Zc is equal to that of the portions 34, and the relative permittivity of the spacing zones Ze is equal to that of the portions 35. As previously indicated, the portions 34 are made of a low-k material, for example a silicon oxide or nitrite, and the portions 35 are made of a high-k material, for example a titanium or tantalum oxide.

As illustrated by FIG. 9B, the variation of the dielectrophoretic force, here the log of ∇₂E², is not identical in the conversion zones Zc and in the spacing zones Ze. More specifically, the minimum in the conversion zones Zc is higher than in the spacing zones Ze. Moreover, the photoluminescent particles p will be deposited in a privileged manner in the conversion zones Zc rather than in the spacing zones Ze.

As illustrated by FIG. 10A, the electret layer 30 is inhomogeneous and is formed of a sublayer formed of a same material with constant relative permittivity, here a low-k material, and portions 40 made of the so-called very high-k material, for which the relative permittivity is equal to at least 100, covers only the spacing zones Ze and not the conversion zones Zc. These portions are made, for example, from a perovskite and/or ferroelectric material, such as BaSrTiO3, BaTiO3, SrTiO3, PbZrTiO3 or KNN, among others. The relative permittivity can be equal to 250. The relative permittivity of the conversion zones Zc is also equal to that of the sublayer of the electret layer (for example: 4), and the relative permittivity of the spacing zones Ze is equal to that of the portions 40 (for example: 250).

As illustrated by FIG. 10B, the variation of the dielectrophoretic force, here the log of ∇₂E², is no longer identical in the conversion zones Zc and in the spacing zones Ze. More specifically, the minimum in the conversion zones Zc is higher than in the spacing zones Ze, and these have a minimum value over a larger surface. Moreover, the photoluminescent particles p will be deposited in a privileged manner in the conversion zones Zc rather than in the spacing zones Ze.

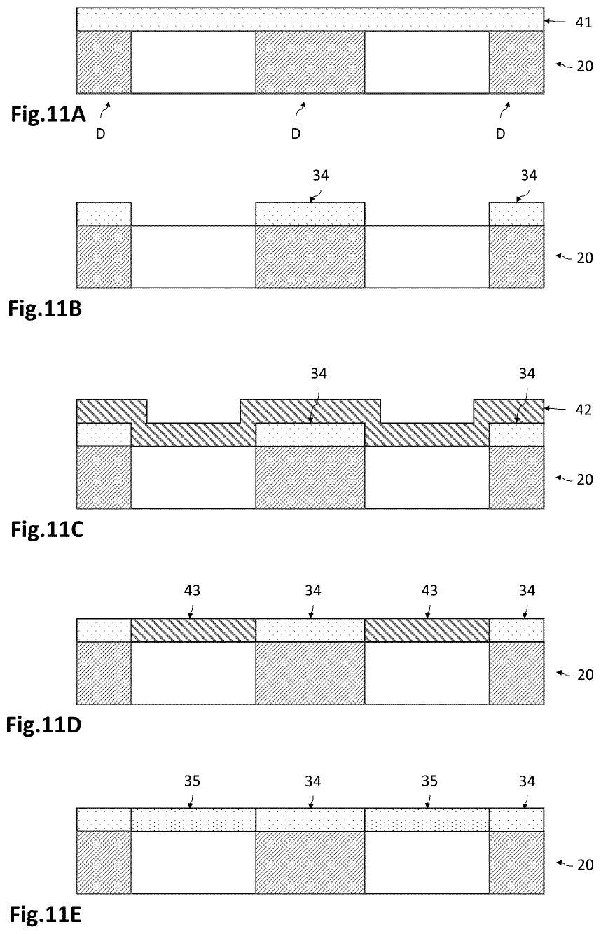

FIGS. 11A to 11E illustrate an example of a method for producing an electret layer formed of a succession of a plurality of portions having different relative permittivity, here portions having the same low relative permittivity, and portions having the same high relative permittivity.

It is also possible to deposit an electret layer 41 formed of the low-k material, which covers the entire diode array 20 (FIG. 11A). Then, through-openings are produced which open onto the diode array 20 in order to form portions 34 situated opposite the diodes (FIG. 11B). Here the openings are through-openings, but they do not need to be. A layer 42 formed of a high-k material is then deposited, or here a metal material such as Ti or Ta, so as to cover the diode array 20 and the portions 34 (FIG. 11C). Then, a chemical mechanical planarization is performed, with a stop on the portions 34 (FIG. 11D). Finally, an oxidation annealing of the metal is carried out in order to obtain the high-k material of the portions 35, here an oxide of Ti or Ta (FIG. 11E).

Particular embodiments have just been described. Different variants and modifications will appear to a person skilled in the art.

1. A method for manufacturing an optoelectronic device, comprising:
providing a diode array, having a front face configured to receive or transmit light radiation;
producing an electret layer, extending on the front face of the diode array, an upper face of which, opposite the front face, has conversion zones, each being situated opposite to a diode and configured to be covered by a color conversion pad, separated two-by-two by a spacing zone with zero surface potential; and
producing the color conversion pads, by placing the electret layer in contact with a colloidal solution containing photoluminescent particles, which are deposited on the electret layer in the conversion zones, thus forming the color conversion pads;
wherein, following producing the electret layer, each conversion zone is formed of a plurality of polarized elementary zones with non-zero surface potential, spaced apart two-by-two by a non-polarized elementary zone with zero surface potential, such that the conversion zone has a structured surface potential.

2. The manufacturing method according to claim 1, wherein the polarized elementary zones of each conversion zone are symmetrically arranged with respect to a center of the conversion zone.

3. The manufacturing method according to claim 1, wherein each conversion zone includes between three and nine polarized elementary zones.

4. The manufacturing method according to claim 1, wherein the polarized elementary zones are all situated at a distance from a border of the conversion zone.

5. The manufacturing method according to claim 1, wherein the electret layer has a homogeneous relative permittivity.

6. The manufacturing method according to claim 1, wherein the electret layer has a relative permittivity having a first value in the conversion zones and a second value greater than the first value outside of the conversion zones.

7. The manufacturing method according to claim 1, wherein the electret layer has a relative permittivity having a first value in the conversion zones and a second value greater than the first value outside of the conversion zones, and wherein the electret layer is formed of first portions situated in the conversion zones and made of a material having the first relative permittivity value, and second portions situated outside of the conversion zones and made of a material having the second relative permittivity value.

8. The manufacturing method according to claim 1, wherein the electret layer has a relative permittivity having a first value in the conversion zones and a second value greater than the first value outside of the conversion zones, and wherein the electret layer is formed of a continuous sublayer covering the diode array and made of a material having the first relative permittivity value, and portions covering the continuous sublayer, situated outside of the conversion zones and made of a material having the second relative permittivity value.

9. An optoelectronic device, comprising:
a diode array having a front face configured to receive or transmit light;
an electret layer, extending on the front face of the diode array, an upper face of which, opposite the front face, has conversion zones, each being situated opposite to a diode and configured to be covered by a color conversion pad, separated two-by-two by a spacing zone with zero surface potential; and
color conversion pads, situated on the electret layer and positioned in the conversion zones;
wherein each conversion zone is formed of a plurality of polarized elementary zones with non-zero surface potential spaced apart two-by-two by a non-polarized elementary zone with zero surface potential, such that the conversion zone has a structured surface potential.

10. The optoelectronic device according to claim 9, wherein diodes of the diode array have light emission or absorption properties identical to one another.

11. The optoelectronic device according to claim 9, wherein diodes of the diode array are made from an organic or inorganic semiconductor compound.
